(19) United States
(12) Patent Application Publication
(10) Pub. No.: US 2009/0227115 A1
(43) Pub. Date: Sep. 10, 2009

(54) ETCHING SOLUTION FOR SUBSTRATE

(75) Inventors: Takehisa Kato, Saitama (JP); Masahiko Kakizawa, Saitama (JP); Ichiro Hayashida, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: WAKO PURE CHEMICAL INDUSTRIES, LTD., Osaka (JP)

(21) Appl. No.: 12/301,549

(22) PCT Filed: May 22, 2007
(86) PCT No.: PCT/JP2007/060415

§ 371 Date: Feb. 13, 2009

(30) Foreign Application Priority Data
May 26, 2006 (JP) 2006-146423

(51) Int. Cl. H01L 21/306; C09K 13/02

(52) U.S. Cl. 438/753; 252/79.5; 438/745; 257/E21.219

(57) ABSTRACT

Disclosed are an etching solution for a substrate and a substrate-etching method, which can prevent the contamination of a substrate, particularly a semiconductor substrate, with metal impurities. The etching solution comprises a dicarboxylic acid represented by the general formula (1) or a salt thereof and 20% (W/W) or more of an alkali metal hydroxide. The substrate-etching method comprises the step of etching a substrate with said etching solution.

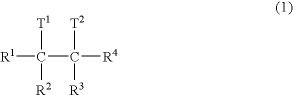

(wherein T¹ and T² independently represent a hydrogen atom, a hydroxyl group, a carboxyl group or an alkyl group having 1 to 3 carbon atoms, or T¹ and T¹ together form a bond; and R¹ to R⁴ independently represent a hydrogen atom, a hydroxyl group, a carboxyl group or an alkyl group having 1 to 3 carbon atoms, provided that, when T¹ and T² do not together form a bond, any two of T¹, T² and R¹ to R⁴ represent a carboxyl group, and any one of the remainder represents a hydroxyl group, and the others independently represent a hydrogen atom or an alkyl group having 1 to 3 carbon atoms, and when T¹ and T² together form a bond, any two of R¹ to R⁴ represent a carboxyl group, and the others independently represent a hydrogen atom or an alkyl group having 1 to 3 carbon atoms.)

### TECHNICAL FIELD

The present invention relates to an etching solution for a substrate, particularly a semiconductor substrate and a substrate-etching method.

### BACKGROUND ART

Semiconductor wafer is generally produced according to the following steps.

(1) Slicing step: a step to obtain a thin disc-like wafer (as-cut wafer) by slicing a single crystal ingot manufactured by FZ process, CZ process, or the like;

(2) Beveling step; a step to chamfer the peripheral part of the as-cut wafer;

(3) Lapping step: a step to obtain a wafer having a uniform thickness (lapped wafer) by both-side lapping of chamfered wafer using loose abrasive grains to make the processing strain layer of the wafer surface thinner and reduce thickness fluctuation and irregularity of the wafer;

(4) Etching step: a step to obtain a clean wafer (etched wafer) by removing the processing strain layer remaining in the lapped wafer by a chemical method (chemical etching), as well as removing abrasives, metal impurities, particles and the like adhered to the wafer surface;

(5) Heat treatment step: a step to vanish an oxidized donor doped in the crystal and stabilize the resistance by applying a heat treatment at low temperature;

(6) Polishing step: a step to obtain a mirror water (polished wafer) having a mirror surface with high flatness by polishing the etched wafer surface with very fine abrasive grains; and

(7) Washing step: a step to obtain cleaner wafer by washing the polished wafer and removing abrasives, metal impurities, particles and the like adhered to the wafer surface.

The chemical etching in the above etching step usually includes 2 types of etching, that is, an acid etching which is carried out by dipping a semiconductor wafer into an acidic solution and an alkali etching which is carried out by dipping into an alkaline solution.

However, since acid etching is difficult to provide uniform etching for wafer due to its fast etching rate and has problems such as deterioration in flatness of wafer and generation of harmful byproducts such as NOₓ and the like, recently alkali etching is more popularly used because it allows uniform etching, exhibits no deterioration in flatness of wafer, and generates less harmful byproducts.

Meanwhile, in the above-described alkali etching of a semiconductor wafer, commercially available industrial or electronics industrial alkaline solution (for example, sodium hydroxide solution, potassium hydroxide solution, or the like) is used. However, industrial alkaline solution contains such a high concentration as around several to ten and several ppm of metal impurities (for example, nickel, chromium, iron, copper, and the like), and even electronics industrial alkaline solution contains around several ten ppb to several ppm of said metal impurities.

When alkali etching is carried out using such alkaline solution as described above, there was a problem that the metal impurities in said solution adhere to wafer and metal ions of said metal impurities diffuse inside of wafer to deteriorate quality of wafer or to lower significantly characteristics of semiconductor devices assembled with said wafer.

In order to solve such problem, various methods have been proposed such as a method in which metal ions in alkaline solution are non-ionized by dissolving metal silicon and/or a silicon compound or hydrogen gas into the alkaline solution in advance (Patent Literature 1), a method in which metal ions in alkaline solution are removed using an ion-exchange resin (Patent Literature 1), a method in which metal ions in alkaline solution are non-ionized by dissolving a reducing agent having base oxidation potential compared to reversible potential of said metal ion such as dithionous acid salt and the like into the alkaline solution (Patent Literature 2). However, even by using these methods, non-ionization or removal of metal ions derived from the metal impurities present in the alkaline solution was insufficient.

Further, in order to solve the above problem, another method has been proposed in which metal ions in alkaline solution are reduced by dipping a stainless steel in alkaline solution for 10 hours or more (Patent Literature 3).

However, this method requires contacting a stainless steel with alkaline solution at elevated temperature for such a long period as 10 hours or more, as well as taking out the stainless steel from alkaline solution and the like, and preparation thereof was cumbersome.

Patent Literature 1: JP-A-9-129624;

Patent Literature 2: JP-A-10-310883;

Patent Literature 3: JP-A-2001-250807.

### DISCLOSURE OF INVENTION

### Problem to be Solved by the Invention

The present invention provides an etching solution for a substrate, particularly a semiconductor substrate and a substrate-etching method, which can reduce the contamination with metal impurities and is useful for solving the above problem.

### Means for Solving Problem

The present invention has been made to solve the above problem, and comprises the following aspects.

(1) An etching solution for a substrate comprising a dicarboxylic acid represented by the following general formula (1):

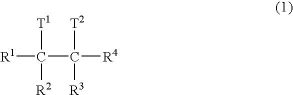

(wherein T¹ and T² each independently represent a hydrogen atom, a hydroxyl group, a carboxyl group or an alkyl group having 1 to 3 carbon atoms, or T¹ and T² together form a bond; and R¹ to R⁴ each independently represent a hydrogen atom, a hydroxyl group, a carboxyl group or an alkyl group having 1 to 3 carbon atoms, provided that, when T¹ and T² do not together form a bond, any two of T¹, T² and R¹ to R⁴ represent a carboxyl group, and any one of the remainder represents a hydroxyl group, and the others each independently represent a hydrogen atom or an alkyl group having 1 to 3 carbon atoms, and when T¹ and T² together form a bond, any two of R¹ to R⁴ represent a carboxyl group, and the others each independently represent a hydrogen atom or an alkyl group having 1 to 3 carbon atoms;)

or a salt thereof, and 20% (W/W) or more of an alkali metal hydroxide.

(2) A substrate-etching method comprising etching a substrate with the etching solution according to the above (1).

Namely, the present inventors have intensively studied to accomplish the above purpose, and found that etching of a substrate, particularly a semiconductor substrate using a solution comprising a specific dicarboxylic acid represented by the general formula (1) or a salt thereof and 20% (W/W) or more of an alkali metal hydroxide can reduce contamination of a semiconductor substrate to be etched with metal impurities, and effectively perform the intended etching, as well as that said solution can be prepared simply and in a short time, and accomplished the present invention.

### EFFECT OF THE INVENTION

By the present invention, in etching of a substrate, particularly a semiconductor substrate, contamination of a semiconductor substrate with metal impurities (adsorption of said metal impurities on the surface of the semiconductor substrate) can be effectively inhibited.

### BEST MODE FOR CARRYING OUT THE INVENTION

The etching solution involved in the present invention comprises at least a dicarboxylic acid represented by the following general formula (1):

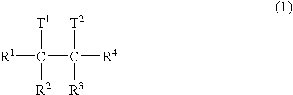

(wherein T¹ and T² each independently represent a hydrogen atom, a hydroxyl group, a carboxyl group or an alkyl group having 1 to 3 carbon atoms, or T¹ and T² together form a bond; and R¹ to R⁴ each independently represent a hydrogen atom, a hydroxyl group, a carboxyl group or an alkyl group having 1 to 3 carbon atoms, provided that, when T¹ and T² do not together form a bond, any two of T¹, T² and R¹ to R⁴ represent a carboxyl group, and any one of the remainder represents a hydroxyl group, and the others each independently represent a hydrogen atom or an alkyl group having 1 to 3 carbon atoms, and when T¹ and T² together form a bond, any two of R¹ to R⁴ represent a carboxyl group, and the others each independently represent a hydrogen atom or an alkyl group having 1 to 3 carbon atoms;)

or a salt thereof (hereinafter, briefly referred to as a dicarboxylic acid involved in the present invention or a salt thereof), and an alkali metal hydroxide.

In the general formula (1), the alkyl group having 1 to 3 carbon atoms represented by T¹ and T² may be linear, branched or cyclic, and includes, for example, methyl group, ethyl group, n-propyl group, isopropyl group and cyclopropyl group. Among them, methyl group is preferable.

In addition, in the general formula (1), the alkyl group having 1 to 3 carbon atoms represented by R¹ to R⁴ may be linear, branched or cyclic, and includes, for example, methyl group, ethyl group, n-propyl group, isopropyl group and cyclopropyl group. Among them, methyl group is preferable.

In the general formula (1), the phrase “T¹ and T² together form a bond” means that a double bond is formed between two carbon atoms (C) in the general formula (1).

Therefore, the dicarboxylic acid involved in the present invention can be classified into two cases where a double bond is formed between two carbon atoms of the general formula (1) and where a single bond is formed.

Among the dicarboxylic acid involved in the present invention, the one in which a double bond is formed between two carbon atoms (C) includes a dicarboxylic acid represented by the following general formula (2):

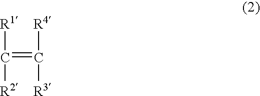

(wherein R^{1′} to R^{4′} each independently represent a hydrogen atom, a carboxyl group or an alkyl group having 1 to 3 carbon atoms, provided that any two of R^{1′} to R^{4′} represent a carboxyl group, the others each independently represent a hydrogen atom or an alkyl group having 1 to 3 carbon atoms).

Incidentally, in the general formula (2), the alkyl group having 1 to 3 carbon atoms represented by R^{1′} to R^{4′} may be linear, branched or cyclic, and includes, for example, methyl group, ethyl group, n-propyl group, isopropyl group and cyclopropyl group. Among them, methyl group is preferable.

Among the dicarboxylic acids represented by the general formula (2) involved in the present invention as described above, the one in which any one of R^{1′} and R^{2′} represents a carboxyl group, any one of R^{3′} and R^{4′} represents a carboxyl group, and the others each independently represent a hydrogen atom or an alkyl group having 1 to 3 carbon atoms in the general formula (2) is preferable.

In addition, in the general formula (2), as for the remaining two substituents other than carboxyl group in R^{1′} to R^{4′}, the one in which at least one substituent represents a hydrogen atom and another substituent represents a hydrogen atom or an alkyl group having 1 to 3 carbon atoms is preferable. Among them, the one in which all of remaining two substituents represent a hydrogen atom is particularly preferable.

The dicarboxylic acid represented by the general formula (2) involved in the present invention as described above includes specifically fumaric acid, maleic acid, dimethyl fumarate, dimethyl maleate, citraconic acid, mesaconic acid, ethyl fumarate, ethyl maleate, and the like. Among them, fumalic acid, maleic acid, citraconic acid, mesaconic acid, and the like are preferable, and fumaric acid and maleic acid are particularly preferable.

Among the dicarboxylic acid involved in the present invention, the one in which a single bond is formed between two carbon atoms (C) includes a dicarboxylic acid represented by is the following general formula (3):

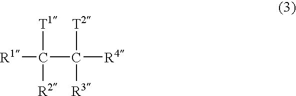

(wherein T^{1″}, T^{2″} and R^{1″} to R^{4″} each independently represent a hydrogen atom, a hydroxyl group, a carboxyl group or an alkyl group having 1 to 3 carbon atoms, provided that any two of T^{1″}, T^{2″} and R^{1″} to R^{4″} represent a carboxyl group, any one of the remainder represents a hydroxyl group, and others each independently represent a hydrogen atom or an alkyl group having 1 to 3 carbon atoms).

Incidentally, in the general formula (3), the alkyl group having 1 to 3 carbon atoms represented by T^{1″}, T^{2″} and R^{1″} to R^{4″} may be linear, branched or cyclic, and includes, for example, methyl group, ethyl group, n-propyl group, isopropyl group and cyclopropyl group. Among them, methyl group is preferable.

Among the dicarboxylic acids represented by the general formula (3) involved in the present invention as described above, the one in which any one of T^{1″}, R^{1″} and R^{2″} represents a carboxyl group, any one of T^{2′}, R^{3″} and R^{4″} represents a carboxyl group, any one of the remainders represents a hydroxyl group, and the others represent each independently a hydrogen atom or an alkyl group having 1 to 3 carbon atoms in the general formula (3) is preferable.

In addition, in the general formula (3), as the remaining three substituents which are neither a carboxyl group nor a hydroxyl group among T^{1″}, T^{2″} and R^{1″} to R^{4″}, the one in which all of the remaining three substituents represent a hydrogen atom is preferable.

The dicarboxylic acid represented by the general formula (3) involved in the present invention as described above includes specifically malic acid, 2,3,3-trimethylmalic acid, 2,3-dimethylmalic acid, 3,3-dimethylmalic acid, 2-methylmalic acid, 3-methylmalic acid, and the like. Among them, malic acid and the like are preferable. Incidentally, malic acid may be D-isomer, L-isomer, DL isomer mixed, or a mixture of D-isomer and L-isomer with varying mixing ratios thereof.

The salt of the dicarboxylic acid involved in the present invention as described above includes, for example, alkali metal salt (sodium salt, potassium salt, lithium salt, cesium salt, and the like), alkaline earth metal salt (calcium salt, magnesium salt, and the like), ammonium salt, alkylammonium salt (tetramethylammonium salt, tetraethylammonium salt, tetrabutylammonium salt, and the like), and the like, and alkali metal salt is preferable. Incidentally, transition metal salt (iron salt, copper salt, cobalt salt, nickel salt, and the like) is not preferable.

Among the dicarboxylic acids or salts thereof involved in the present invention as described above, the one selected from fumaric acid, maleic acid, citraconic acid, mesaconic acid, malic acid and salt thereof is particularly preferable.

Incidentally, the dicarboxylic acids or salts thereof involved in the present invention as described above may be used alone or in a suitable combination of two or more kinds.

Amount to be used of the dicarboxylic acid or salt thereof involved in the present invention cannot be categorically determined because it varies depending on the kind of the dicarboxylic acid or salt thereof involved in the present invention, amount to be used of the alkali metal hydroxide together, and the like, but, for example, the lower limit is generally 50 ppm or more, preferably 100 ppm or more, and more preferably 1,000 ppm or more, and the upper limit is generally the amount of saturation or less, preferably 10,000 ppm or less, and more preferably 5,000 ppm or less.

The alkali metal hydroxide to be used in the present invention includes sodium hydroxide, potassium hydroxide, and the like.

These alkali metal hydroxides may be used alone or in a suitable combination of two or more kinds.

In addition, amount to be used of the alkali metal hydroxide cannot be categorically determined because it varies depending on the kind of the alkali metal hydroxide and the like, but the lower limit is generally 20% (W/W) or more, preferably 40% (W/W) or more, and more preferably 45% (W/W) or more, and the upper limit is generally 60% (W/W) or less, preferably 55% (W/W) or less, and more preferably 52% (W/W) or less.

The etching solution of the present invention comprises a dicarboxylic acid or a salt thereof involved in the present invention as described above and such a high concentration as 20% (W/W) or more of an alkali metal hydroxide.

The etching solution of the present invention is usually in a state of aqueous solution, and prepared by mixing and dissolving the dicarboxylic acid or a salt thereof involved in the present invention and a high concentration of an alkali metal hydroxide in water so that their concentrations fall within the concentration ranges as described above, respectively.

Method for dissolving the dicarboxylic acid or a salt thereof and an alkali metal hydroxide involved in the present invention in water is not particularly limited, as long as each of these components can be finally mixed and dissolved in water by the method. Examples of the method include a method in which the dicarboxylic acid or a salt thereof and/or the alkali metal hydroxide involved in the present invention separately dissolved in water in advance are (is) added, a method in which the dicarboxylic acid or a salt thereof and the alkali metal hydroxide involved in the present invention are added directly to water followed by stirring and dissolving, and the like. That is, each of the components may be sequentially added and dissolved in water in a suitable order, or alternatively all components may be added to water at the same time then dissolved.

The etching solution involved in the present invention thus prepared is preferably subjected to a filtration treatment or the like before use. In addition, water to be used here may be one purified by means of distillation, ion-exchange treatment, and the like, but more preferable one is so-called ultrapure water which is commonly used in this industry.

Incidentally, in the present invention, when the etching solution of the present invention is prepared, the dicarboxilic acid or a salt thereof involved in the present invention as described above itself may be used, or alternatively an acid anhydride (for example, maleic anhydride, citraconic anhydride, and the like), which is formed via dehydration-condensation of two carboxyl groups (—COOH) in the dicarboxylic acid or a salt thereof involved in the present invention, may be used. That is, when an etching solution of the present invention is prepared using an acid anhydride, the acid anhydride reacts with water in the solution (the etching solution) to form easily a dicarboxylic acid. As a result, the dicarboxylic acid involved in the present invention is present in the resultant solution (the etching solution). Similarly, it is obvious that an ester of the dicarboxylic acid involved in the present invention may be used.

The etching solution of the present invention is strongly alkaline, and usually has a pH value of 13 or higher.

Further, in the etching solution involved in the present invention, an additive, which is commonly used in this industry, can be used aside from the dicarboxylic acid or a salt thereof and the alkali metal hydroxide involved in the present invention as described above. Such additive includes, for example, chelating agent [aminopolycarboxylic acid type chelating agent or inorganic salt thereof], surfactant, oxidizing agent [hydrogen peroxide, ozone, oxygen, and the like], silicon, dissolved gas [argon, nitrogen, and the like], and the like.

That is, the etching solution involved in the present invention includes the one which contains one kind of additive selected from chelating agent, surfactant, oxidizing agent, silicon, and dissolved gas. Incidentally, in the present invention, use of a substance exhibiting a reducing nature (for example, reducing agent, hydrogen, and the like) is not preferable.

The chelating agent to be used in the present invention may be any one which is commonly used in this industry, and includes, for example, aminopolycarboxylic acid type chelating agent, phosphonic acid type chelating agent, N-substituted amino acids, amides, condensed phosphoric acids, alkanoylketones, inorganic ions, and the like.

Among these chelating agents, aminopolycarboxylic acid type chelating agent is particularly preferable.

The aminopolycarboxylic acid type chelating agent as described above includes, for example, nitrogen-containing polycarboxylic acids having 1 to 4 nitrogen atoms and 2 to 6 carboxy groups in a molecule, such as alkyliminopolycarboxylic acid which may have a hydroxyl group [hydroxyethyliminodiacetic acid (HIDA), iminodiacetic acid (IDA), and the like], nitrilopolycarboxylic acid [nitrilotriacetic acid (NTA), nitrilotripropionic acid (NTP), and the like], monoalkylenepolyaminepolycarboxylic acid [ethylenediaminetetraacetic acid (EDTA), ethylenediaminediacetic acid (EDDA), ethylenediaminedipropionic acid dihydrochloride (EDDP), hydroxyethylethylenediaminetriacetic acid (EDTA-OH), 1,6-hexamethylenediamine-N,N,N′,N′-tetraacetic acid (HDTA), N,N-bis(2-hydroxylbenzyl)ethylenediamine-N,N-diacetic acid (HBED), and the like], polyalkylenepolyaminepolycarboxylic acid [diethylenetriamine-N,N,N′,N″,N″-pentaacetic acid (DTPA), triethylenetetraminehexaacetic acid (TTHA), and the like], polyaminoalkanepolycarboxylic acid [diaminopropanetetraacetic acid (Methyl-EDTA), trans-1,2-diaminocyclohexane-N,N,N′,N′-tetraacetic acid (CyDTA), and the like], polyaminoalkanolpolycarboxylic acid [diaminopropanoltetraacetic acid (DPTA-OH), and the like], hydroxyalkyletherpolyaminepolycarboxylic acid [glycoletherdiaminetetraacetic acid (GEDTA), and the like], and the like.

In addition, inorganic salt thereof includes, for example, alkali metal salt [sodium salt, potassium salt, lithium salt, cesium salt, and the like], alkaline earth metal salt [calcium salt, magnesium salt], and the like, and alkali metal salt is preferable.

Among them, monoalkylenepolyaminecarboxylic acid, polyalkylenepolyaminecarboxylic acid or inorganic salt thereof is preferable, and polyalkylenepolyaminecarboxylic acid or inorganic salt thereof is particularly preferable. In addition, specifically, EDTA, DTPA or inorganic salt thereof is preferable, and DTPA or inorganic salt thereof is particularly preferable.

These aminopolycarboxylic acid type chelating agents or inorganic salts thereof may be used alone or in a suitable combination of two or more kinds.

The phosphonic acid type chelating agent includes, for example, nitrogen-containing polyphosphonic acids having 1 to 3 nitrogen atoms and 2 to 5 phosphonic acid groups in a molecule such as aminopoly(alkylphosphonic acid) [aminotris(methylenephosphonic acid), and the like], nitrilopoly(alkylphosphonic acid) [nitrilotris(methylenephosphonic acid) (NTPO), and the like], mono or polyalkylenepolyaminepoly(alkylphosphonic acid) [ethylenediaminetetrakis(methylenephosphonic acid) (EDTPO), ethylenediamine-N,N′-bis(methylenephosphonic acid) (EDDPO), isopropylenediaminetetrakis(methylenephosphonic acid), diethylenetriamine-N,N,N′,N″,N″-penta(methylenephosphonic acid), ethylenediaminebis(methylenephosphonic acid), hexenediaminetetrakis(methylenephosphonic acid), and the like], alkylaminopoly(alkylphosphonic acid) [ethylaminobis(methylenephosphonic acid), dodecylaminobis(methylenephosphonic acid), and the like], and the like, and alkanepolyphosphonic acids which may have a hydroxyl group such as methydiphosphonic acid, ethylidendiphosphonic acid, 1-hydroxyethylidene-1,1′-diphosphonic acid (HEDPO), 1-hydroxypropylidene-1,1′-diphosphonic acid, 1-hydroxybutylidene-1,1′-diphosphonic acid, and the like.

The N-substituted amino acids include, for example, dihydroxyethylglycine (DHEG), N-acetylglycine, and the like.

The amides include, for example, benzylamide and the like.

The condensed phosphoric acids include, for example, tripolyphosphoric acid, hexametaphosphoric acid, and the like.

The alkanoylketones include, for example, acetylacetone, hexafluoroacetylacetone, and the like.

The inorganic ions include, for example, halide ion (F⁻, Cl⁻, Br⁻, I⁻), cyanide ion, for example, thiocyanate ion, thiosultate ion, ammonium ion, and the like.

Amount to be used of the chelating agent as described above cannot be categorically determined because it varies depending on the kind of the chelating agent, amount to be used of the alkali metal hydroxide to be used together, and the like, but, for example, the lower limit is generally 50 ppm or more, preferably 100 ppm or more, and more preferably 1,000 ppm or more, and the upper limit is generally the amount of saturation or less, preferably 10,000 ppm or less, and more preferably 5,000 ppm or less.

Silicon source (material to be used) includes metal silicon [polycrystalline or single-crystal silicon] and silicon compound [for example, silica, silicate glass, and the like], and amount to be used of silicon is 2 g/L or more.

The surfactant as described above includes, but not limited to, for example, nonionic surfactant having polyoxyalkylene group in a molecule; for example, anionic surfactant having a group selected from sulfonic acid group, carboxyl group, phosphonic acid group, sulfoxyl group and phosphonoxyl group in a molecule; for example, alkylamine; for example, quaternary ammonium such as alkyltrimethylammonium, alkyldimethylbenzylammonium, and the like; for example, cationic surfactant such as alkylpyridinium, salt thereof (for example, hydrochloride, sulfate, and the like); and for example, amphoteric surfactant such as alkylbetaine derivative, imidazoliumbetaine derivative, sulfobetaine derivative, aminocarboxylic acid derivative, imidazoline derivative, amineoxide derivative, and the like. The nonionic surfactant having a polyoxyalkylene group in a molecule includes, for example, polyoxyalkylene alkyl ether, polyoxyalkylene polyalkylaryl ether, and the like, and more specifically, for example, nonionic surfactant having a polyoxyethylene group in a molecule such as polyoxyethylene alkyl ether, polyoxyethylene alkylphenyl ether, and the like; for example, nonionic surfactant having a polyoxypropylene group in a molecule such as polyoxypropylene alkyl ether, polyoxypropylene alkylphenyl ether, and the like; nonionic surfactant having a polyoxyethylene group and a polyoxypropylene group in a molecule such as polyoxyethylenepolyoxypropylene alkyl ether, polyoxyethylenepolyoxypropylene alkylphenyl ether, and the like; and the like. The anionic surfactant having a group selected from sulfonic acid group, carboxyl group, phosphonic acid group, sulfoxyl group and phosphonoxyl group in a molecule includes, for example, anionic surfactant having a sulfonic acid group such as alkylsulfonic acid, alkylbenzenesulfonic acid, alkylnaphthalenesulfonic acid, salt thereof (for example, salt of alkali metal such as sodium, potassium, and the like, ammonium salt, and the like; among them ammonium salt is preferable), and the like; for example, anionic surfactant having a carboxyl group in a molecule such as alkylcarboxylic acid, alkylbenzenecarboxylic acid, alkylnaphthalenecarboxylic acid, salt thereof (for example, salt of alkali metal such as sodium, potassium, and the like, ammonium salt, and the like; among them ammonium salt is preferable), and the like; for example, anionic surfactant having a phosphonic acid group in a molecule such as alkylphosphonic acid, alkylbenzenephosphonic acid, alkylnaphthalenephosphonic acid, salt thereof (for example, salt of alkali metal such as sodium, potassium, and the like, ammonium salt, and the like; among them ammonium salt is preferable), and the like; and for example, anionic surfactant having a sulfoxyl group in a molecule such as alkyl sulfate ester, alkylbenzene sulfate ester, polyoxyethylene alkylsulfate ester, polyoxyethylene alkylbenzenesulfate ester, polyoxyethylene alkylnaphthalenesulfate ester, salt thereof (for example, salt of alkali metal such as sodium, potassium, and the like, ammonium salt, and the like; among them ammonium salt is preferable), and the like. Among them, nonionic surfactant and anionic surfactant are preferable. Further, as the nonionic surfactant, polyoxyalkylene alkyl ether is particularly preferable, and as the anionic surfactant, the one having a sulfonic acid group or a sulfoxyl group in a molecule is particularly preferable. More specifically, nonionic surfactant having a polyoxyethylene group in a molecule such as polyoxyethylene alkyl ether, and the like; nonionic surfactant having a polyoxyethylene group and a polyoxypropylene group in a molecule such as polyoxyethylenepolyoxypropylene alkyl ether, and the like; anionic surfactant having a carboxyl group in a molecule such as alkylbenzenesulfonic acid, and the like; and anionic surfactant having a sulfoxyl group in a molecule such as polyoxyethylene alkylsufate ester, and the like are particularly preferable. In addition, these surfactants may be used alone or in a suitable combination of two or more kinds. Amount to be used of the surfactant cannot be categorically determined because it varies depending on the kind of the surfactant, but is generally 0.0001 to 1% by weight, preferably 0.0001 to 0.1% by weight, and more preferably 0.0001 to 0.05% by weight.

Etching method of the present invention may be such method that a substrate is contacted with the etching solution of the present invention as described above to treat said substrate with the etching solution of the present invention.

That is, the etching method of the present invention may be performed according to any known etching method such as dip method and spray etching method, except that a substrate is etched using the etching solution involved in the present invention which comprises a dicarboxylic acid or a salt thereof involved in the present invention as described above and an alkali metal hydroxide.

More specifically, the method includes, for example, the following: (1) a method in which a substrate is dipped in the etching solution, (2) a method in which s substrate is dipped in the etching solution while said solution is stirred by a mechanical means, (3) a method in which a substrate is dipped in the etching solution while said solution is vibrated and stirred by ultrasonic wave, (4) a method in which the etching solution is sprayed to a substrate, and the like.

Incidentally, in the method of the present invention, a substrate may be oscillated if necessary, when the etching as described above is carried out.

In addition, in the method of the present invention, etching style is not particularly limited, and any style such as, for example, batch style, sheet-leaf style, and the like can be employed.

Incidentally, as the temperature condition in the etching, the lower limit is generally room temperature or higher, preferably 60° C. or higher, and more preferably 65° C. or higher, and the upper limit is generally 100° C. or lower, preferably 90° C. or lower, and more preferably 85° C. or lower. That is, the temperature of the etching solution of the present invention is set within the above temperature range, and a substrate may be contacted with the solution.

Substrate to which the etching solution and the etching method of the present invention are applied may be any one, as long as it is commonly used in this industry. The substrate includes semiconductor substrate including silicon type material such as silicon, amorphous silicon, polysilicon, silicon oxide film, silicon nitride film, compound semiconductors such as gallium-arsenic, gallium-phosphorous, indium-phosphorous; glass substrate such as LCD; and the like. And kind of the substrate differs depending on purpose to use the etching solution (the etching method).

Among them, the treating agent and the treating method of the present invention are suitably used for a semiconductor substrate, in particular, a semiconductor substrate comprising silicon type material.

Hereinafter, the present invention will be explained more in detail referring to Examples and Comparative Examples, but the present invention is by no means limited by them.

### Example 1

### (1) Preparation of Etching Solution

To a solution of 48% NaOH (manufactured by Shin-Yo Chemical Industries Co., Ltd.) solution containing traces of Fe, Ni and Cu as impurities, the prescribed additives were added in prescribed amount as shown in Table 1.

### (2) Etching

After each etching solution obtained in the above (1) was heated to 85° C., etching treatment (85° C.) was carried out by dipping a 6 inch wafer into each of these solutions for 5 minutes. The wafers were taken out, washed with flowing water, then washed with pure water, and spin-dried.

### (3) Results

Amounts of metals on the surface of the etched wafers obtained in the above (2) were determined using a total reflection X-ray fluorescence spectrometer (“TREX 610”, manufactured by Technos Co., Ltd.).

Results are shown in Table 1. Incidentally, the mark [symbol] in Table 1, means “or less”.

TABLE 1

| | | Addition | Adsorbed metal amount | | |
|---|---|---|---|---|---|
| | | amount | (×10¹⁰ atoms/cm²) | | |
| No | Additive | (ppm) | Fe | Ni | Cu |
| 1 | Nil | — | 9,900 | 5,600 | 43 |
| 2 | Fumaric acid | 500 | 91 | 1 | 0.3↓ |
| 3 | Maleic acid | 500 | 34 | 6 | 0.3↓ |
| 4 | Citraconic acid | 500 | 240 | 60 | 0.3↓ |
| 5 | Mesaconic acid | 500 | 210 | 42 | 0.3↓ |
| 6 | DL-Malic acid | 500 | 200 | 36 | 0.3↓ |
| 7 | Oxalic acid | 1,000 | 7,600 | 4,900 | 25 |
| 8 | Sorbic acid | 500 | 11,000 | 6,800 | 44 |
| 9 | Crotonic acid | 500 | 8,700 | 4,600 | 33 |
| 10 | L-Asparaginic acid | 1,000 | 7,700 | 4,600 | 15 |
| 11 | Succinic acid | 500 | 9,600 | 6,200 | 37 |
| 12 | L(+)-Tartaric acid | 500 | 9,000 | 5,100 | 33 |
| 13 | Itaconic acid | 500 | 8,700 | 4,600 | 129 |

As is clear from Table 1, it can be found that the dicarboxylic acids involved in the present invention, that is, the dicarboxylic acids having a specific structure represented by the general formula (1) (fumaric acid, maleic acid, citraconic acid, mesaconic acid, and DL-malic acid) exhibit a high inhibitory effect for adsorption of metals on the surface of the semiconductor substrate (No. 2 to 6), whereas the monocarboxylic acids (sorbic acid, crotonic acid) and the dicarboxylic acids not included in the general formula (1) of the present invention (L-asparaginic acid, succinic acid, L(+)-tartaric acid and itaconic acid) has a low inhibitory effect for the adsorption (No. 7 to 13).

### Example 2

### (1) Preparation of Etching Solution

Preparation was carried out in the same manner as in Example 1, except that DL-malic acid as an additive was used in the prescribed amounts as shown in Table 2.

### (2) Etching

Etching was carried out in the same manner as in Example 1.

### (3) Results

Amounts of metals on the surface of etched wafers were determined in the same manner as in Example 1. Results are shown in Table 2. Incidentally, the mark [symbol] in Table 1 means “or less”.

TABLE 2

| | Adsorbed metal amount | | |
|---|---|---|---|
| Addition amount of | (×10¹⁰ atoms/cm²) | | |
| DL-malic acid | Fe | Ni | Cu |
| Nil | 9,900 | 5,600 | 43 |

| | | | | |
|---|---|---|---|---|
| 10 | ppm | 9,100 | 5,500 | 40 |
| 50 | ppm | 520 | 310 | 10 |
| 100 | ppm | 410 | 280 | 9 |
| 500 | ppm | 200 | 36 | 0.3↓ |
| 1,000 | ppm | 100 | 23 | 0.3↓ |
| 5,000 | ppm | 51 | 10 | 0.3↓ |
| 10,000 | ppm | 33 | 3 | 0.3↓ |

As is clear from Table 2, it can be found that DL-malic acid exhibits a good inhibitory effect for adsorption of metals at the concentration in the etching solution of 50 ppm or more, in particular, higher effect at the concentration of 1,000 ppm or more.

### Example 3

### (1) Preparation of Etching Solution

To the prescribed concentration of NaOH (manufactured by Shin-Yo Chemical Industries Co., Ltd.) solution (containing traces of Fe, Ni and Cu as impurities) shown in Table 3, 1,000 ppm of DL-malic acid was added.

### (2) Etching

After the etching solutions obtained in the above (1) were heated up to 85° C., etching treatment (85° C.) was carried out by dipping wafer pieces (2 cm×2 cm) into these solutions for 5 minutes.

### (3) Results

Roughness of the surfaces of the wafer pieces obtained in the above (2) were measured by an atomic force microscope (“Nanopics 2100”, manufactured by Seiko Instruments Inc.).

Results are shown in Table 3.

TABLE 3

| Concentration used | Average plane roughness |
|---|---|
| (%) | (nm) |
| 10 | 140 |
| 20 | 12 |
| 48 | 9 |
| Before treatment | 8 |

As is clear from Table 3, it can be found that as for amount to be used of NaOH, concentration in the etching solution is preferably 20% (W/W) or more because it roughens the surface of the semiconductor substrate in a lower concentration.

### Example 4

### (1) Preparation of Etching Solution

Preparation was carried out in the same manner as in Example 1, except that prescribed amounts of malic acid as shown in Table 4 were used as an additive.

### (2) Etching

Etching was carried out in the same manner as in Example 1.

### (3) Results

Amounts of metals on the surface of etched wafers were measured in the same manner as in Example 1.

Results are shown in Table 4.

TABLE 4

| | | Addition | Adsorbed metal amount | | |
|---|---|---|---|---|---|
| | | amount | (×10¹⁰ atoms/cm²) | | |
| No | Additive | (ppm) | Fe | Ni | Cu |
| 1 | Nil | — | 9,900 | 5,600 | 43 |
| 2 | DL-Malic acid | 2,000 | 55 | 6 | 1 |
| 3 | L-Maleic acid | 2,000 | 154 | 13 | 4 |
| 4 | D-Malic acid | 2,000 | 61 | 6 | 2 |

As is clear from Table 4, it can be found that malic acid in any form of DL isomer mixed or either of optical isomers (L-isomer and D-isomer) exhibits inhibitory effect for adsorption of metals on the semiconductor substrate surface. Among them, DL isomer mixed and D-isomer are found to have a higher inhibitory effect for adsorption (No. 2 and 4).

### Example 5

### (1) Preparation of Etching Solution

Preparation was carried out in the same manner as in Example 1, except that prescribed additives shown in Table 5 were used in the prescribed amount.

### (2) Etching

Etching was carried out in the same manner as in Example 1.

### (3) Results

Amounts of metals on the surface of etched wafers were measured in the same manner as in Example 1.

Results are shown in Table 5. Incidentally, the mark [symbol] in Table 5 means “or less”. And also, in Table 5, each of abbreviations for additives means the followings, respectively.
EDTA: Ethylenediaminetetraacetic acid
DTPA: Diethylenetriamine-N,N,N′,N″,N″-pentaacetic acid

TABLE 5

| | | Addition | Adsorbed metal amount | | |
|---|---|---|---|---|---|
| | | amount | (×10¹⁰ atoms/cm²) | | |
| No | Additive | (ppm) | Fe | Ni | Cu |
| 1 | Nil | — | 9,900 | 5,600 | 43 |
| 2 | Fumaric acid | 500 | 91 | 1 | 0.3↓ |
| 3 | Maleic acid | 500 | 34 | 6 | 0.3↓ |
| 4 | Citraconic acid | 500 | 240 | 60 | 0.3↓ |
| 5 | Mesaconic acid | 500 | 210 | 42 | 0.3↓ |
| 6 | DL-Malic acid | 500 | 200 | 36 | 0.3↓ |
| 7 | EDTA | 500 | 1,600 | 410 | 9 |
| 8 | DTPA | 500 | 940 | 380 | 7 |
| 9 | EDTA | 500 | 210 | 40 | 0.3↓ |
| | DL-Malic acid | | | | |
| 10 | DTPA | 500 | 190 | 32 | 0.3↓ |
| | DL-Malic acid | | | | |

As is clear from Table 5, it can be found that although aminopolycarboxylic acid such as EDTA and DTPA have an inhibitory effect for adsorption of metals on the semiconductor substrate surface (No. 7 to 8), the dicarboxylic acids involved in the present invention, that is, the dicarboxylic acids (fumaric acid, maleic acid, citraconic acid, mesaconic acid and DL-malic acid) having a specific structure represented by the general formula (1) have a higher inhibitory effect for adsorption of metals on the semiconductor substrate surface (No. 2 to 6). It can be also found that combined use of the dicarboxylic acid of the present invention and the aminopolycarboxylic acid also exhibits the similar level of inhibitory effect for adsorption of metals on the semiconductor substrate surface to that of single use of the dicarboxylic acid of the present invention (No. 9 to 10).

### Example 6

### (1) Preparation of Etching Agent

To a solution of 48% KOH (manufactured by Wako Pure Chemical Industries, Ltd.) solution containing traces of Fe, Ni and Cu as impurities, the prescribed additives were added each in prescribed amount as shown in Table 6.

### (2) Etching

Etching was carried out in the same manner as in Example 1.

### (3) Results

Amounts of metals on the surface of etched wafers were measured in the same manner as in Example 1.

Results are shown in Table 6. Incidentally, the mark [symbol] in Table 6 means “or less”.

TABLE 6

| | | Addition | Adsorbed metal amount | | |
|---|---|---|---|---|---|
| | | amount | (×10¹⁰ atoms/cm²) | | |
| No | Additive | (ppm) | Fe | Ni | Cu |
| 1 | Nil | — | 3,500 | 100 | 170 |
| 2 | Fumaric acid | 1,000 | 30 | 0.3↓ | 0.3↓ |
| 3 | Maleic acid | 1,000 | 18 | 0.3↓ | 0.3↓ |
| 4 | Citraconic acid | 1,000 | 22 | 0.3↓ | 0.3↓ |
| 5 | Mesaconic acid | 1,000 | 45 | 0.3↓ | 0.3↓ |
| 6 | DL-Malic acid | 1,000 | 15 | 0.3↓ | 0.3↓ |

As is clear from Table 6, it can be found that when KOH is used as the alkali metal hydroxide, the dicarboxylic acids involved in the present invention, that is, the dicarboxylic acids having a specific structure represented by the general formula (1) (fumaric acid, maleic acid, citraconic acid, mesaconic acid and DL-malic acid) also exhibit a high inhibitory effect for adsorption of metals (No. 2 to 6).

### INDUSTRIAL APPLICABILITY

By etching a substrate, particularly a semiconductor substrate using the etching solution involved in the present invention, contamination of the semiconductor substrate to be etched with metal impurities (adsorption of said metal impurities on the semiconductor substrate surface) in the etching process can be reduced.

1. An etching solution for a substrate comprising a dicarboxylic acid represented by the following general formula (1): 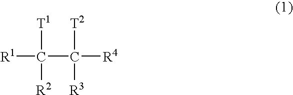
(wherein T¹ and T² each independently represent a hydrogen atom, a hydroxyl group, a carboxyl group or an alkyl group having 1 to 3 carbon atoms, or T¹ and T² together form a bond; and R¹ to R⁴ each independently represent a hydrogen atom, a hydroxyl group, a carboxyl group or an alkyl group having 1 to 3 carbon atoms, provided that, when T¹ and T² do not together form a bond, any two of T¹, T² and R¹ to R⁴ represent a carboxyl group, and any one of the remainder represents a hydroxyl group, and the others each independently represent a hydrogen atom or an alkyl group having 1 to 3 carbon atoms, and when T¹ and T² together form a bond, any two of R¹ to R⁴ represent a carboxyl group, and the others each independently represent a hydrogen atom or an alkyl group having 1 to 3 carbon atoms;)
or a salt thereof, and 20% (W/W) or more of an alkali metal hydroxide.

2. The etching solution according to claim 1, wherein the alkali metal hydroxide is sodium hydroxide or potassium hydroxide.

3. The etching solution according to claim 1, wherein the etching solution comprises 50 ppm or more of said dicarboxylic acid or a salt thereof.

4. The etching solution according to claim 1, wherein said dicarboxylic acid or a salt thereof is the one selected from a group consisting of fumaric acid, maleic acid, citraconic acid, mesaconic acid, malic acid and a salt thereof.

5. The etching solution according to claim 1, wherein a pH value thereof is 13 or higher.

6. The etching solution according to claim 1, wherein the substrate is a semiconductor substrate.

7. A substrate-etching method comprising etching a substrate with the etching solution according to claim 1.

8. The etching method according to claim 7, wherein temperature of the etching solution is 60 to 100° C.

9. The etching method according to claim 7, wherein the substrate is a semiconductor substrate.

10. The etching method according to claim 9, wherein the semiconductor substrate comprises a silicon type material.
